(19) United States
(12) Patent Application Publication
(10) Pub. No.: US 2024/0288774 A1
(43) Pub. Date: Aug. 29, 2024

(54) COMPOSITION FOR REMOVING EDGE BEAD OF METAL-CONTAINING RESIST AND METHOD FOR FORMING PATTERN COMPRISING STEP OF REMOVING EDGE BEAD BY USING SAME

(71) Applicant: SAMSUNG SDI CO., LTD., Yongin-si, Gyeonggi-do (KR)

(72) Inventors: Minyoung LEE, Suwon-si (KR); Hyungrang MOON, Suwon-si (KR); Ryunmin HEO, Suwon-si (KR); Minsoo KIM, Suwon-si (KR); Youngkwon KIM, Suwon-si (KR); Jaehyun KIM, Suwon-si (KR); Changsoo WOO, Suwon-si (KR)

(21) Appl. No.: 18/570,518

(22) PCT Filed: Jun. 27, 2022
(86) PCT No.: PCT/KR2022/009104

§ 371 Date: Dec. 14, 2023

(30) Foreign Application Priority Data
Jul. 8, 2021 (KR) 10-2021-0089811
May 18, 2022 (KR) 10-2022-0061047

(51) Int. Cl. G03F 7/16; G03F 7/004

(52) U.S. Cl. CPC G03F 7/168; G03F 7/0042

(57) ABSTRACT

Provided are composition for removing edge beads from metal-containing resists, and a method of forming patterns including step of removing edge beads using the same and the composition includes an organic solvent and a cyclic compound substituted with at least one hydroxy group (—OH),
wherein the cyclic compound has a carbon number of 5 to 30, and
the cyclic compound has at least one double bond in the ring.

### TECHNICAL FIELD

This disclosure relates to a composition for removing edge beads from metal-containing resists, and a method of forming patterns including step of removing edge beads using the same.

### BACKGROUND ART

In recent years, a semiconductor industry has been accompanied by a continuous reduction of critical dimensions, and this dimensional reduction requires new types of high-performance photoresist materials and a patterning method that satisfy a demand for processing and patterning with increasingly smaller features.

In addition, with the recent rapid development of the semiconductor industry, a semiconductor device is required of a fast operation speed and large storage capacity, and in line with this requirement, process technology for improving integration, reliability, and a response speed of the semiconductor device is being developed. Particularly, it is important to accurately control/implant impurities in working regions of a silicon substrate and to interconnect these regions to form a device and an ultra-high-density integrated circuit, which may be achieved by a photolithographic process. In other words, it is important to integrate the photolithographic process including coating a photoresist on the substrate, selectively exposing it to ultraviolet (UV) (including extreme ultraviolet (UV)), electron beams, X rays, or the like, and then, developing it.

Particularly, in the process of forming the photoresist layer, the resist is coated on the substrate, mainly while rotating the silicon substrate, wherein the resist is coated on an edge and rear surface of the substrate, which may cause indentation or pattern defects in the subsequent semiconductor processes such as etching and ion implantation processes. Accordingly, a process of stripping and removing the photoresist coated on the edge and rear surface of the silicon substrate by using a thinner composition, that is, an EBR (edge bead removal) process is performed. The EBR process requires a composition that exhibits excellent solubility for the photoresist and effectively removes beads and the photoresist remaining in the substrate and generates no resist residue.

### DISCLOSURE

### Technical Problem

An embodiment provides a composition for removing edge beads from metal-containing resists.

Another embodiment provides a method of forming patterns including the step of removing the edge beads using the composition.

### Technical Solution

The composition for removing edge beads from the metal-containing resists according to an embodiment includes an organic solvent and a cyclic compound substituted with at least one hydroxy group (—OH), wherein the cyclic compound has 5 to 30 carbon numbers and the cyclic compound has at least one double bond in the ring.

The cyclic compound may be substituted with one or two hydroxyl groups (—OH).

The cyclic compound may have 5 to 20 carbon atoms.

The cyclic compound may have 5 to 10 carbon atoms.

The cyclic compound may be represented by any one of Chemical Formula 1 to Chemical Formula 3.

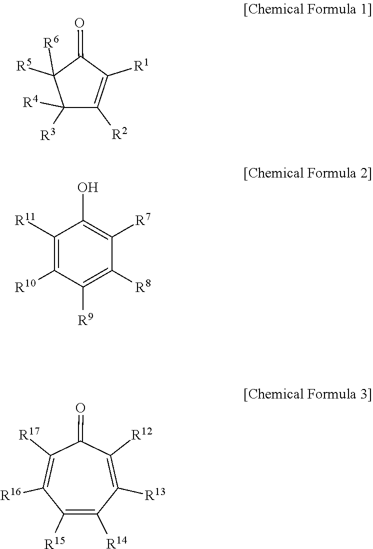

In Chemical Formula 1 to Chemical Formula 3,
R¹ to R¹⁷ are each independently hydrogen, a halogen, a hydroxy group, an amino group, a substituted or unsubstituted C1 to C30 amine group, a substituted or unsubstituted C1 to C10 alkyl group, or a substituted or unsubstituted C6 to C20 aryl group, and
at least one of R¹ to R⁶, at least one of R⁷ to R¹¹, and at least one of R¹² to R¹⁷ are a hydroxyl group.

The cyclic compound may be selected from the chemical formulas of Group 1.

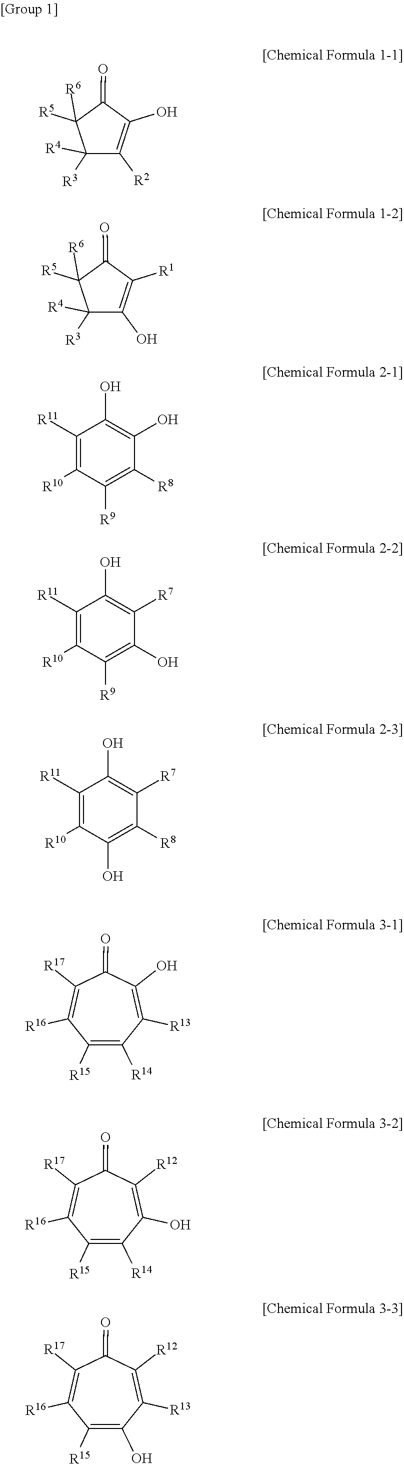

In Group 1,
R¹ to R¹⁷ are each independently hydrogen, a halogen, an amino group, a substituted or unsubstituted C1 to C30 amine group, a substituted or unsubstituted C1 to C10 alkyl group, or a substituted or unsubstituted C6 to C20 aryl group.

The cyclic compound may be selected from compounds of Group 2.

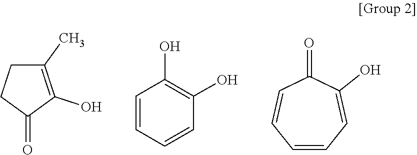

The composition for removing edge beads from metal-containing resists may include 50 to 99.99 wt % of the organic solvent; and 0.01 to 50 wt % of the cyclic compound.

The metal compound included in the metal-containing resists may include at least one of an alkyl tin oxo group and an alkyl tin carboxyl group.

The metal compound included in the metal-containing resists may be represented by Chemical Formula 4.

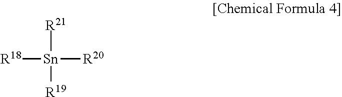

In Chemical Formula 4,
R¹⁸ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and —R^{a}—O—R^{b} (wherein R^{a} is a substituted or unsubstituted C1 to C20 alkylene group and R^{b} is a substituted or unsubstituted C1 to C20 alkyl group),
R¹⁹ to R²¹ are each independently selected from —OR^{c} or—OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

A method of forming patterns according to another embodiment includes coating a metal-containing resist composition on a substrate, coating the aforementioned composition for removing edge beads from the metal-containing resists along the edge of the substrate, drying and heating the coated resultant to form a metal-containing resist film on the substrate, and exposing and developing the dried and heated resultant to form a resist pattern.

The method of forming patterns may further include coating the aforementioned composition for removing edge beads from the metal-containing resists is coated along the edge of the substrate again after the exposing and developing.

### Advantageous Effects

The composition for removing edge beads from the metal-containing resists according to an embodiment reduces the metal-based contamination inherent in the metal-containing resists and removes the resist coated on the edge and the rear surface of the substrate, thereby satisfying requirements of processing and patterning of smaller features.

### DESCRIPTION OF THE DRAWINGS

FIG. 1 is a schematic view of a photoresist coating apparatus.

<Description of symbols>

| | |
|---|---|
| 1: substrate support portion | 2: spray nozzle |
| 10: photoresist solution | 12: edge bead |

### BEST MODE

Hereinafter, embodiments of the present invention is described in detail with reference to the accompanying drawings. In the following description of the present disclosure, the well-known functions or constructions will not be described in order to clarify the present disclosure.

In order to clearly illustrate the present disclosure, the description and relationships are omitted, and throughout the disclosure, the same or similar configuration elements are designated by the same reference numerals. Also, since the size and thickness of each configuration shown in the drawing are arbitrarily shown for better understanding and ease of description, the present disclosure is not necessarily limited thereto.

In the drawings, the thickness of layers, films, panels, regions, etc., are exaggerated for clarity. In the drawings, the thickness of a part of layers or regions, etc., is exaggerated for clarity. It will be understood that when an element such as a layer, film, region, or substrate is referred to as being “on” another element, it can be directly on the other element or intervening elements may also be present.

In the present disclosure, “substituted” refers to replacement of a hydrogen atom by deuterium, a halogen group, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a cyano group. “Unsubstituted” means that a hydrogen atom remains as a hydrogen atom without being replaced by another substituent.

In the present disclosure, when a definition is not otherwise provided, the term “cyclic compound” refers to a compound having a structure in which the terminal atoms constituting a molecule are linked to each other to form a ring, and according to the type of atoms forming the ring, it may be classified into a ‘carbocyclic compound’ and a ‘heterocyclic compound’.

The ‘carbocyclic compound’ refers to a compound in which a ring-forming atom is only carbon.

The ‘heterocyclic compound’ refers to a compound including a hetero atom in addition to carbon atoms forming a ring.

The hetero atom that may be contained in the ‘heterocyclic compound’ may include, but is not limited to, N, O, S, P, Si, and the like.

In the present disclosure, the term “alkyl group” means a linear or branched aliphatic hydrocarbon group, unless otherwise defined. The alkyl group may be a “saturated alkyl group” that does not contain any double or triple bonds.

The alkyl group may be a C1 to C20 alkyl group. More specifically, the alkyl group may be a C1 to C10 alkyl group or a C1 to C6 alkyl group. For example, a C1 to C4 alkyl group means that the alkyl chain contains 1 to 4 carbon atoms, and may be selected from methyl, ethyl, propyl, iso-propyl, n-butyl, iso-butyl, sec-butyl, and t-butyl.

Specific examples of the alkyl group include a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, or a cyclohexyl group, etc.

In the present disclosure, when a definition is not otherwise provided, the term “cycloalkyl group” refers to a monovalent cyclic aliphatic hydrocarbon group.

In the present disclosure, when a definition is not otherwise provided, the term “alkenyl group” is a linear or branched aliphatic hydrocarbon group, and refers to an aliphatic unsaturated alkenyl group containing one or more double bonds.

In the present disclosure, when a definition is not otherwise provided, the term “alkynyl group” is a linear or branched aliphatic hydrocarbon group, and refers to an unsaturated alkynyl group containing one or more triple bonds.

In the present disclosure, “aryl group” means a substituent in which all elements of a cyclic substituent have p-orbitals, and these p-orbitals form a conjugate and may include monocyclic or fused ring polycyclic (i.e., rings that share adjacent pairs of carbon atoms) functional groups.

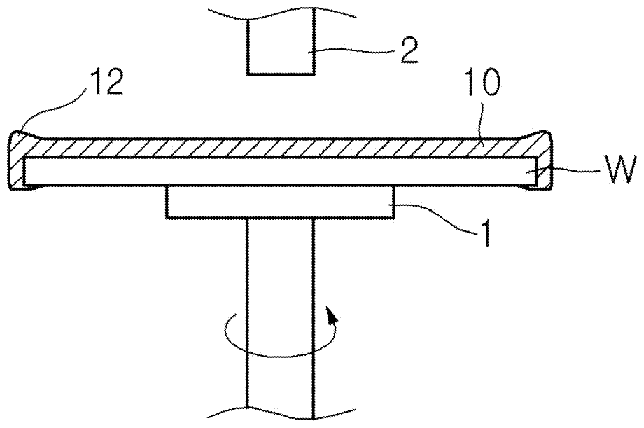

FIG. 1 is a schematic view of a photoresist coating apparatus.

Referring to FIG. 1, a substrate support portion 1 on which a substrate W is placed is provided, and the substrate support portion 1 includes a spin chuck or a spin coater.

The substrate support portion 1 rotates in a first direction at a predetermined rotation speed, and provides a centrifugal force to the substrate W. A spray nozzle 2 is disposed on the substrate support portion 1, and the spray nozzle 2 is located in an atmospheric area deviating from the upper portion of the substrate W and moves to the upper portion of the substrate during the solution supply step to spray a photoresist solution 10. Accordingly, the photoresist solution 10 is coated on the surface of the substrate by the centrifugal force. At this time, the photoresist solution 10 supplied to the center of the substrate W is coated while being spread to the edge of the substrate W by centrifugal force, and a portion thereof is moved to the side surface of the substrate and the lower surface of the edge of the substrate.

That is, in the coating process, the photoresist solution 10 is mainly coated by a spin coating method. By supplying a predetermined amount of viscous photoresist solution 10 to the center of the substrate W, it gradually spreads toward the edge of the substrate by centrifugal force.

Therefore, the thickness of the photoresist is formed to be flat by the rotation speed of the substrate support portion.

However, as the solvent evaporates, the viscosity gradually increases, and a relatively large amount of photoresist is accumulated on the edge of the substrate by the action of surface tension. More seriously, photoresist is accumulated up to the lower surface of the edge of the substrate, which is referred to as edge beads 12.

Hereinafter, a composition for removing edge beads from metal-containing resists according to an embodiment is described.

The composition for removing edge beads from the metal-containing resists according to an embodiment of the present invention includes an organic solvent, and a cyclic compound substituted with at least one hydroxy group (—OH), wherein the cyclic compound has a carbon number of 5 to 30 and the cyclic compound has at least one double bond in the ring.

The “double bond” is included in at least one in the ring, a form in which the double bond is continuously included is excluded due to the nature of the rigid structure of the cyclic compound. The ‘having at least one double bond in the ring’ means that one double bond is included via at least one single bond.

The composition for removing edge beads from the metal-containing resists includes a cyclic compound substituted with a hydroxyl group (—OH), and the hydroxyl group (—OH) is coordinated with the metal-containing resist, and by coating the composition including the same, the metal-containing resists may be effectively removed.

For example, the cyclic compound may be substituted with one or two hydroxyl groups (—OH).

The cyclic compound may have 5 to 20 carbon atoms, for example 5 to 10 carbon atoms.

For example, the cyclic compound may have 6 to 20 carbon atoms.

As a specific example, the cyclic compound may have 6 to 10 carbon atoms.

For example, the cyclic compound may be represented by any one of Chemical Formula 1 to Chemical Formula 3.

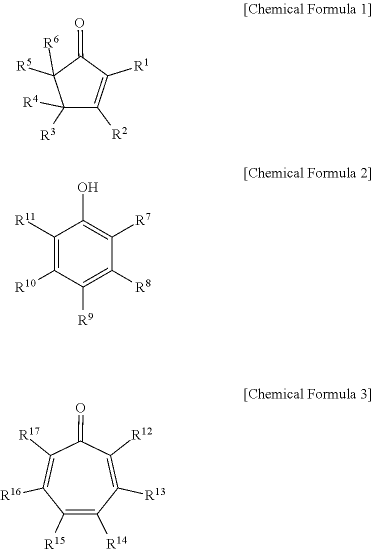

In Chemical Formula 1 to Chemical Formula 3,
R¹ to R¹⁷ are each independently hydrogen, a halogen, a hydroxy group, an amino group, a substituted or unsubstituted C1 to C30 amine group, a substituted or unsubstituted C1 to C10 alkyl group, or a substituted or unsubstituted C6 to C20 aryl group, and
at least one of R¹ to R⁶, at least one of R⁷ to R¹¹, and at least one of R¹² to R¹⁷ is a hydroxyl group.

As a specific example, the cyclic compound may be selected from the chemical formulas of Group 1.

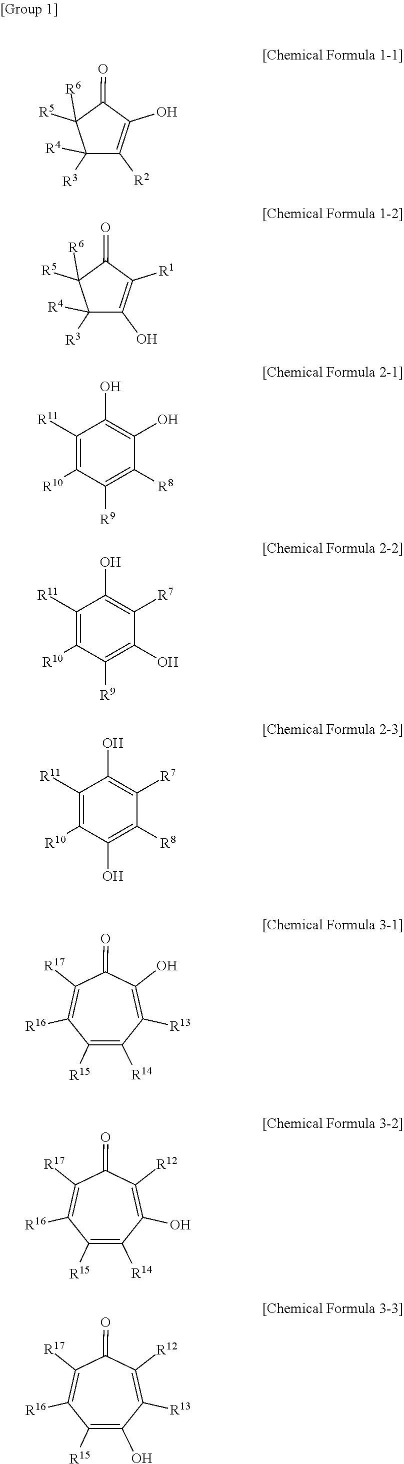

In Group 1,
R¹ to R¹⁷ are each independently hydrogen, a halogen, an amino group, a substituted or unsubstituted C1 to C30 amine group, a substituted or unsubstituted C1 to C10 alkyl group, or a substituted or unsubstituted C6 to C20 aryl group.

For example, the cyclic compound may be selected from compounds of Group 2.

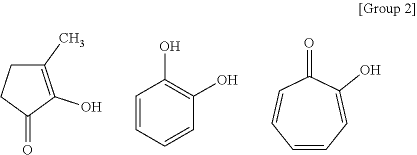

In an example embodiment, the composition for removing edge beads from metal-containing resists may include 50 to 99.99 wt % of the organic solvent and 0.01 to 50 wt % of the aforementioned cyclic compound.

In a specific embodiment, the composition for removing edge beads from the metal-containing resists may include the aforementioned cyclic compound in an amount of 0.05 to 40 wt %, specifically 0.5 to 30 wt %, or more specifically about 1 to 20 wt %.

The organic solvent included in the composition for removing edge beads from the metal-containing resists according to an embodiment may be for example propylene glycol methyl ether (PGME), propylene glycol methyl ether acetate (PGMEA), propylene glycol butyl ether (PGBE), ethylene glycol methyl ether, diethylglycolethylmethylether, dipropylglycoldimethylether, ethanol, 2-butoxyethanol, n-propanol, isopropanol, n-butanol, isobutanol, hexanol, ethylene glycol, propylene glycol, heptanone, propylene carbonate, butylene carbonate, diethyl ether, dibutyl ether, ethyl acetate, methyl 3-methoxypropionate, ethyl 3-ethoxypropionate, diisopentyl ether, xylene, acetone, methylethylketone, methylisobutylketone, tetrahydrofuran, dimethylsulfoxide, dimethyl formamide, acetonitrile, diacetone alcohol, 3,3-dimethyl-2-butanone, N-methyl-2-pyrrolidone, dimethyl acetamide, cyclohexanone, gamma butyrolactone (GBL), 1-butanol (n-butanol), ethyl lactate (EL), diene butylether (DBE), diisopropyl ether (DIAE), acetylacetone, 4-methyl-2-pentenol (or referred to as methyl isobutyl carbinol (MIBC)), 1-methoxy-2-propanol, 1-ethoxy-2-propanol, toluene, xylene, methylethylketone, cyclopentanone, cyclohexanone, 2-hydroxyethyl propionate, 2-hydroxy-2-methylethyl propionate, ethoxyethyl acetate, hydroxyethyl acetate, 2-hydroxy-3-methylmethyl butanoate, 3-methoxymethyl propionate, 3-methoxyethyl propionate, 3-ethoxyethyl propionate, 3-ethoxymethyl propionate, methyl pyruvate, ethyl pyruvate, ethyl acetate, butyl acetate, ethyl lactate, butyl lactate(n-butylactate), methyl-2-hydroxyisobutyrate (HBM), methoxy benzene, n-butyl acetate, 1-methoxy-2-propyl acetate, methoxyethoxy propionate, ethoxyethoxy propionate, or a mixture thereof, but is not limited thereto.

The composition for removing edge beads from the metal-containing resists according to the present invention may be particularly effective in removing metal-containing resists, more specifically undesirable metal residues such as tin-based metal residues.

The metal compound included in the metal-containing resists may include at least one of an alkyl tin oxo group and an alkyl tin carboxyl group.

For example, the metal compound included in the metal-containing resists may be represented by Chemical Formula 4.

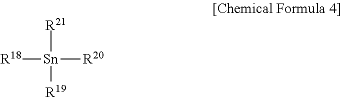

In Chemical Formula 4,
R¹⁸ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and —R^{a}—O—R^{b} (wherein R^{a} is a substituted or unsubstituted C1 to C20 alkylene group, and R^{b} is a substituted or unsubstituted C1 to C20 alkyl group),
R¹⁹ to R²¹ are each independently selected from —OR^{c} or—OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

Meanwhile, according to another embodiment, a method of forming patterns includes the step of removing the edge beads using the aforementioned composition for removing edge beads from the metal-containing resist. For example, the manufactured pattern may be a photoresist pattern. More specifically, it may be a negative-type photoresist pattern.

The method of forming patterns according to an embodiment includes coating a metal-containing resist composition on a substrate, coating the aforementioned composition for removing edge beads from the metal-containing resists along the edge of the substrate, drying and heating the coated resultant to form a metal-containing resist film on the substrate, and exposing and developing the dried and heated resultant to form a resist pattern.

More specifically, the forming of patterns using the metal-containing resist composition may include coating a metal-containing resist composition on a substrate on which a thin film is formed by spin coating, slit coating, inkjet printing, etc., and drying the coated metal-containing resist composition to form a photoresist film. The metal-containing resist composition may include a tin-based compound, for example, the tin-based compound may include at least one of an alkyl tin oxo group and an alkyl tin carboxyl group.

More specifically, the aforementioned composition for removing edge beads from the metal-containing resists along the edge of the substrate may be coated while rotating the substrate at an appropriate speed (e.g., 500 rpm or more).

Subsequently, a first heat treatment process of heating the substrate on which the photoresist film is formed is performed. The first heat treatment process may be performed at a temperature of about 80° C. to about 120° C. and in this process, the solvent is evaporated and the photoresist film may be more firmly adhered to the substrate.

And the photoresist film is selectively exposed.

For example, examples of light that may be used in the exposure process may include not only light having a short wavelength such as i-line (wavelength 365 nm), KrF excimer laser (wavelength 248 nm), ArF excimer laser (wavelength 193 nm), but also EUV (light having a high energy wavelength such as EUV (Extreme UltraViolet, wavelength 13.5 nm), E-Beam (electron beam), etc.

More specifically, the light for exposure according to an embodiment may be short-wavelength light having a wavelength range of about 5 nm to about 150 nm, and light having a high energy wavelength such as EUV (Extreme UltraViolet, wavelength 13.5 nm), E-Beam (electron beam), etc.

In the step of forming the photoresist pattern, a negative-type pattern may be formed.

The exposed region of the photoresist film has a solubility different from that of the unexposed region of the photoresist film as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist film becomes difficult to be dissolved in a developing solution.

Specifically, the photoresist pattern corresponding to the negative tone image may be completed by dissolving and removing the photoresist film corresponding to the unexposed region using an organic solvent such as 2-heptanone.

The developing solution used in the method of forming patterns according to the embodiment may be an organic solvent, for example, ketones such as methyl ethyl ketone, acetone, cyclohexanone, or 2-haptanone, alcohols such as 4-methyl-2-propanol, 1-butanol, isopropanol, 1-propanol, or methanol, esters such as propylene glycol monomethyl ether acetate, ethyl acetate, ethyl lactate, n-butyl acetate, butyrolactone, aromatic compounds such as benzene, xylene, or toluene, or a combination thereof.

In addition, the method of forming patterns may further include coating the composition for removing edge beads from the metal-containing resists after the exposing and developing. Specifically, the method may include coating an appropriate amount of the composition for removing edge beads from the metal-containing resists along the edge of the substrate while rotating the substrate at an appropriate speed (e.g., 500 rpm or more).

As described above, the photoresist pattern formed by exposure to not only light having a wavelength such as i-line (wavelength 365 nm), KrF excimer laser (wavelength 248 nm), ArF excimer laser (wavelength 193 nm), but also EUV (Extreme UltraViolet; wavelength 13.5 nm), but also light having high energy such as an E-beam (electron beam) may have a thickness width of about 5 nm to about 100 nm. For example, the photoresist pattern may be formed to have a thickness width of 5 nm to 90 nm, 5 nm to 80 nm, 5 nm to 70 nm, 5 nm to 60 nm, 5 nm to 50 nm, 5 nm to 40 nm, 5 nm to 30 nm, or 5 nm to 20 nm.

On the other hand, the photoresist pattern may have a pitch having a half-pitch of less than or equal to about 50 nm, for example less than or equal to 40 nm, for example less than or equal to 30 nm, for example less than or equal to 20 nm, for example less than or equal to 15 nm and a line width roughness of less than or equal to about 10 nm, less than or equal to about 5 nm, less than or equal to about 3 nm, or less than or equal to about 2 nm.

### MODE FOR INVENTION

Hereinafter, the present invention will be described in more detail through examples relating to the preparation of the aforementioned composition for removing edge beads from metal-containing resists. However, the technical features of the present invention are not limited by the following examples.

### Preparation of Composition for Removing Edge Beads of Metal-Containing Resist

### Example 1

The cyclic compound represented by Chemical Formula A and propylene glycol methyl ether acetate (PGMEA) as a solvent were mixed in the composition shown in Table 1, and then completely dissolved by shaking at room temperature (25° C.). Then, the final composition is obtained by passing a PTFE filter having a pore size of 1 μm.

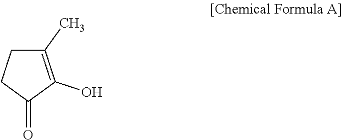

### Example 2

A composition was obtained in the same manner as in Example 1, except that the cyclic compound represented by Chemical Formula B and methylisobutylcarbinol (MIBC) as a solvent were used.

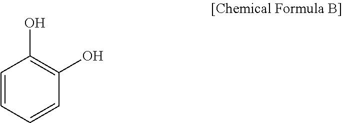

### Comparative Example 1

A composition was obtained in the same manner as in Example 1, except that glycerol was used instead of the compound of Chemical Formula A.

### Comparative Example 2

A composition was obtained in the same manner as in Example 1, except that acetic acid was used instead of the compound of Chemical Formula A.

### Comparative Example 3

A composition was obtained in the same manner as in Example 1, except that acetone oxime was used instead of the compound of Chemical Formula A.

### Comparative Example 4

A composition was obtained in the same manner as in Example 1, except that tetra-n-butylammonium fluoride (TBAF) was used instead of the compound of Chemical Formula A.

### Preparation Example: Preparation of Organometal-Containing Photoresist Composition

An organometallic compound having a structure of Chemical Formula C was dissolved at a concentration of 1 wt % in 4-methyl-2-pentanol and then, filtered through a 0.1 μm PTFE syringe filter, obtaining a photoresist composition.

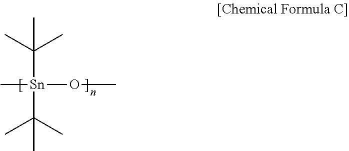

### Evaluation: Evaluation of Residual Film Thickness (Strip Test) and Evaluation of Sn Residual Amount Before Development

1.0 mL of the organometal compound-containing photoresist composition according to preparation example was cast on a 6-inch silicon wafer, allowed to stand for 20 seconds, and then, spin-coated at 800 rpm for 30 seconds. Then, a thickness of the coated film obtained by heat treating at 180° C. for 60 seconds was measured by ellipsometry. 10 mL of each composition for removing edge beads prepared in Example 1, Example 2, and Comparative Example 1 to Comparative Example 4 was added along the edge on the wafer on which the coated film was formed, spin-coated for 5 seconds and then dried while rotating it at a speed of 1,500 rpm. Then, a thickness of each film obtained by heat treating at 150° C. for 60 seconds was re-measured by the ellipsometry method, and a thickness change before and after the edge bead removal process was checked and evaluated according to the following criteria. VPD ICP-MS analysis was performed to confirm the Sn residual amount, and the results are shown in Table 1.
the residual thickness is less than 2 Å: ◯, the residual thickness is more than 2 Å: X

TABLE 1

| | Composition for removing | | | |
|---|---|---|---|---|
| | edge beads from the | | | Sn residual |
| | metal-containing resists | | | amount |
| | | Solvent | Strip | (×10¹⁰ |
| | Compound | (wt %) | test | atoms/cm²) |
| Example 1 | Chemical Formula A | PGMEA | ◯ | 90 |
| | (10 wt %) | (90 wt %) | | |
| Example 2 | Chemical Formula B | MIBC | ◯ | 40 |
| | (10 wt %) | (90 wt %) | | |
| Comparative | glycerol (10 wt %) | PGMEA | X | 3700 |
| Example 1 | | (90 wt %) | | |
| Comparative | acetic acid (10 wt %) | PGMEA | X | 1100 |
| Example 2 | | (90 wt %) | | |
| Comparative | acetone oxime (10 | PGMEA | X | 6500 |
| Example 3 | wt %) | (90 wt %) | | |
| Comparative | TBAF (10 wt %) | PGMEA | X | 5300 |
| Example 4 | | (90 wt %) | | |

Referring to Table 1, the composition for removing the edge bead from the metal-containing resists according to Examples 1 and 2 exhibited more improved metal removal effect compared with the composition for removing the edge beads from the metal-containing resists according to Comparative Examples 1 to 4, and further promoted reduction of residual metals.

Hereinbefore, the certain embodiments of the present invention have been described and illustrated, however, it is apparent to a person with ordinary skill in the art that the present invention is not limited to the embodiment as described, and may be variously modified and transformed without departing from the spirit and scope of the present invention. Accordingly, the modified or transformed embodiments as such may not be understood separately from the technical ideas and aspects of the present invention, and the modified embodiments are within the scope of the claims of the present invention.

1. A composition for removing edge beads from metal-containing resists, comprising
an organic solvent, and
a cyclic compound substituted with at least one hydroxy group (—OH),
wherein the cyclic compound has a carbon number of 5 to 30, and
the cyclic compound has at least one double bond in the ring.

2. The composition of claim 1, wherein
the cyclic compound is substituted with one or two hydroxyl groups (—OH).

3. The composition of claim 1, wherein
the cyclic compound has 5 to 20 carbon atoms.

4. The composition of claim 1, wherein
the cyclic compound has 5 to 10 carbon atoms.

5. The composition of claim 1, wherein
the cyclic compound is represented by any one of Chemical Formula 1 to Chemical Formula 3: 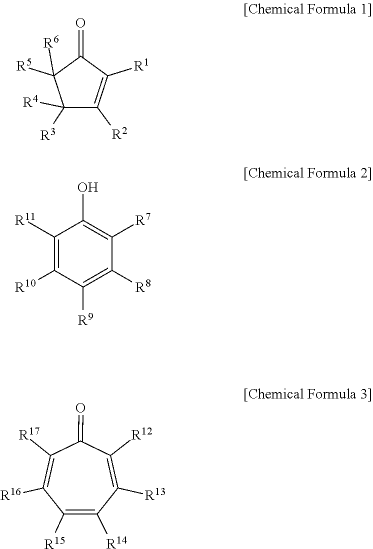
wherein, in Chemical Formula 1 to Chemical Formula 3,
R¹ to R¹⁷ are each independently hydrogen, a halogen, a hydroxy group, an amino group, a substituted or unsubstituted C1 to C30 amine group, a substituted or unsubstituted C1 to C10 alkyl group, or a substituted or unsubstituted C6 to C20 aryl group, and
at least one of R¹ to R⁶, at least one of R⁷ to R¹¹, and at least one of R¹² to R¹⁷ is a hydroxyl group.

6. The composition of claim 1, wherein
the cyclic compound is selected from the chemical formulas of Group 1: 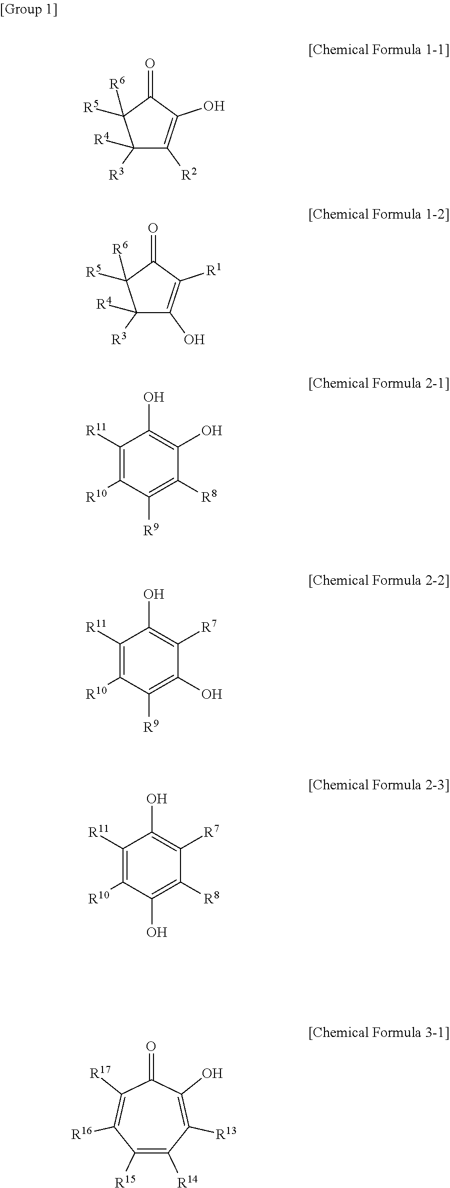 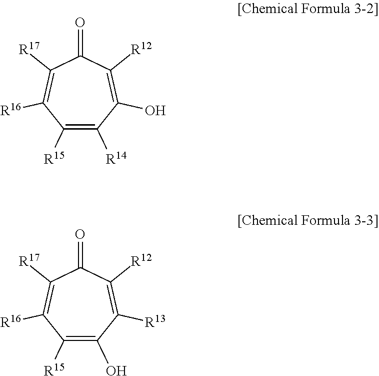
wherein, in Group 1,
R¹ to R¹⁷ are each independently hydrogen, a halogen, an amino group, a substituted or unsubstituted C1 to C30 amine group, a substituted or unsubstituted C1 to C10 alkyl group, or a substituted or unsubstituted C6 to C20 aryl group.

7. The composition of claim 1, wherein
the cyclic compound is selected from compounds of Group 2:

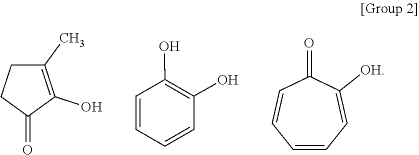

8. The composition of claim 1, wherein
the cyclic compound is included in an amount of 0.01 to 50 wt %; and
the organic solvent is included in an amount of 50 to 99.99 wt %.

9. The composition of claim 1, wherein
a metal compound included in the metal-containing resists includes at least one of an alkyl tin oxo group and an alkyl tin carboxyl group.

10. The composition of claim 1, wherein
a metal compound included in the metal-containing resists is represented by Chemical Formula 4: 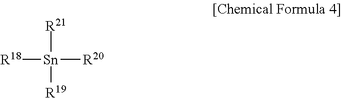
wherein, in Chemical Formula 4,
R¹⁸ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and —R^{a}—O—R^{b} (wherein R^{a} is a substituted or unsubstituted C1 to C20 alkylene group and R^{b} is a substituted or unsubstituted C1 to C20 alkyl group),
R¹⁹ to R²¹ are each independently selected from —OR^{c} or —OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

11. A method of forming patterns, comprising
coating a metal-containing resist composition on a substrate;
coating the aforementioned composition for removing edge beads from the metal-containing resists claim 1 along the edge of the substrate;
drying and heating the coated resultant to form a metal-containing resist film on the substrate; and
exposing and developing the dried and heated resultant to form a resist pattern.

12. The method of claim 11, wherein
the composition for removing edge beads from the metal-containing resists is coated along the edge of the substrate again after the exposing and developing.
